(19) United States
(12) Patent Application Publication
(10) Pub. No.: US 2013/0168812 A1
(43) Pub. Date: Jul. 4, 2013

(54) MEMORY CAPACITOR HAVING A ROBUST MOAT AND MANUFACTURING METHOD THEREOF

(71) Applicants: TZUNG-HAN LEE, TAIPEI CITY (TW); CHUNG-LIN HUANG, TAOYUAN COUNTY (TW); RON-FU CHU, TAIPEI CITY (TW)

(72) Inventors: TZUNG-HAN LEE, TAIPEI CITY (TW); CHUNG-LIN HUANG, TAOYUAN COUNTY (TW); RON-FU CHU, TAIPEI CITY (TW)

(73) Assignee: INOTERA MEMORIES, INC., TAOYUAN COUNTY (TW)

(21) Appl. No.: 13/426,848

(22) Filed: Mar. 22, 2012

(30) Foreign Application Priority Data
Jan. 4, 2012 (TW) 101100351

(51) Int. Cl. H01L 29/92; H01L 21/02

(52) U.S. Cl. 257/532; 438/386; 257/E21.008; 257/E29.343

(57) ABSTRACT

A manufacturing method for memory capacitor having a robust moat, comprising the steps of: providing a substrate; forming a patterned sacrificial layer on the substrate having a moat to separate a cell area and a peripheral area; forming a supporting layer on the sacrificial layer and filling the moat to form a annular member, wherein the supporting layer and the sacrificial layer arranged in alignment to form a stack structure; forming a plurality row of capacitor trenches on the substrate, wherein the capacitor trenches are formed at intervals in the stack structure; and forming a conducting layer on the supporting layer and covering the substrate and the inner surface of the stack structure defining the capacitor trenches.

### BACKGROUND OF THE INVENTION

1. Field of the Invention

The instant disclosure relates to a manufacturing method for memory capacitor; in particular to a manufacturing method for memory capacitor having a robust moat structure.

2. Description of Related Art

The random access memory (RAM) is a form of computer data storage, which includes transistors, capacitors and peripheral controlling unit. For increasing the computer performance, it is important to increase the surface of the capacitors to improve the electric charge stored on the capacitors.

However, conventional manufacturing method for memory capacitor mainly forms a moat and a plurality of capacitors concurrently through a single etching step. When the critical dimension of the capacitor trenches is changed by adjusting process parameters, the adjustment will also affect the critical dimension of the moat. To the contrary, when the critical dimension of the moat is changed by adjusting process parameters, the adjustment will also affect the critical dimension of the capacitor trenches. Additionally, the moat may be easily damaged by a following wet etching step, which causes defects thereto. Hence, the manufacturing yield rate is negatively affected.

To address the above issues, the inventors strive via industrial experience and academic research to present the instant disclosure, which can effectively improve the limitations described above.

### SUMMARY OF THE INVENTION

The object of the instant disclosure is to provide a manufacturing method for memory capacitor having a robust moat, thereby promoting the manufacturing yield. On the other hand, the memory capacitor fabricated by the manufacturing method of the present invention improves the structure strength and the property of electric capacity.

In order to achieve the aforementioned objects, according to an embodiment of the instant disclosure, a manufacturing method for memory capacitor is provided, which includes the steps of: providing a substrate; forming a patterned sacrificial layer on the substrate, the patterned sacrificial layer including a moat that surroundingly defines an array area therein and a peripheral area thereout; forming a supporting structure by filling the moat to form an annular member and disposing a supporting layer on the sacrificial layer over the annular member, the supporting layer and the sacrificial layer forming a stack structure; forming a plurality row of capacitor trenches in the array area through the supporting layer and the sacrificial layer of the stack structure; and forming a conducting layer on the supporting layer and the inner surface of the capacitor trench.

Based on the above, a memory capacitor is further provided, which includes a substrate, a stack structure, a plurality row of capacitor trench structures, a supporting structure, and a conducting layer. The substrate includes a designated array area, and the stack structure formed on the substrate. The capacitor trench structures are formed through the stack structure in the array area electrically connected to the substrate. The supporting structure includes an insulating supporting moat structure arranged around the capacitor trench structures through the stack structure and an integrally connected supporting layer over the supporting moat structure. The conducting layer is disposed on the supporting layer in connection with the capacitor trench structures.

In comparison with prior art, the manufacturing method of the present invention using two etching step to form the moat and the capacitor trenches separately. Thus, the critical dimensions of the moat and the capacitor trenches are easily controlled by adjusting process parameters such as gaseous flow, process time, etc. Thereby, the capacitor trenches are uniform. Furthermore, the annular member fabricated by the manufacturing method having a moat and a supporting layer filled therein. Thus, the supporting layer will be used as a mask to protect the moat form damaging by following a wet etching step using stronger acid. Thereby, the manufacturing method can improve the manufacturing yield.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1-6 shows the steps of the manufacturing method for memory capacitor having a robust moat in accordance to an embodiment of the instant disclosure.

### DETAILED DESCRIPTION OF THE PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings.

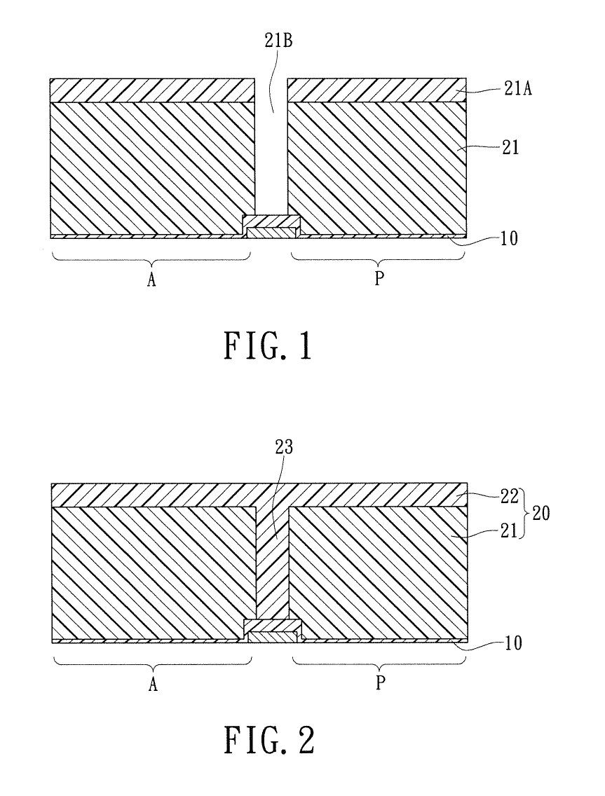

Please refer to FIGS. 1 to 6, the present invention discloses a manufacturing method of memory capacitor having a robust moat, comprising the following steps:

As shown in FIG. 1, step (a) is providing a substrate 10. The substrate 10 has a plurality of conducting plugs (not shown) formed therein and a plurality of sources (drains) of transistors (not shown) which are electrically connected to the conducting plugs. The conducting plugs are made of poly silicon.

Step (b) is forming a patterned sacrificial layer 21 on the substrate 10. In the embodiment, the sacrificial layer 21 includes one or more silicon oxide layer, such as BPSG, PSG, or USG, etc. The step (b) includes the steps of executing a lithography process to form a patterned photoresist layer 21A on the sacrificial layer 21, then removing the exposed sacrificial layer 21 by a dry etching step to define a moat 21B. Specially, the moat 21B is used to separate an Array area A and a peripheral area P.

As shown in FIG. 2, step (c) is forming a supporting layer 22 on the sacrificial layer 21 and subsequently executing a polishing process (ex. Chemical Mechanical Polishing) to make the surface of the sacrificial layer 21 more smoother. In the embodiment, the supporting layer 22 and the sacrificial layer 21 arranged in alignment to form a stack structure 20, and the supporting layer 22 is a silicon nitride (SiN) layer which is insulating. Specially, the moat 21B filled with the supporting layer 22 during deposition process to form an annular member 23. Thereby, the supporting layer 22 will be used as a mask to protect the moat 21B form damaging by following a wet etching step using stronger acid.

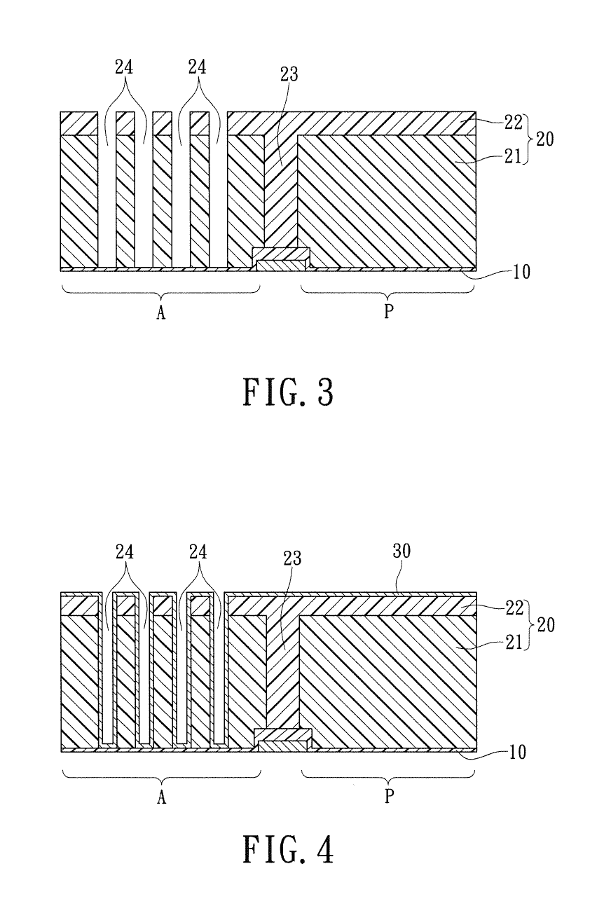

As shown in FIG. 3, step (d) is forming a plurality row of capacitor trenches 24 on the substrate 10. In the embodiment, The step (d) includes the steps of forming a patterned photoresist layer (not shown) on the supporting layer 22, then removing the exposed sacrificial layer 21 and supporting layer 22 to form the capacitor trenches 24 which are cylindrical-in shape. In other words, the capacitor trenches 24 are formed at intervals in the stack structure 20 and will act as capacitors for the stack DRAM. On the other hand, the step (d) further comprises forming a stopping layer (not shown) on the supporting layer 22, wherein the supporting layer 22 is made of carbonaceous material. Additionally, the stopping layer having a predetermined thickness is utilized as a mask during said removing procedure, so the stack structure 20 is substantially perpendicular to the substrate 10.

As shown in FIG. 4, step (e) is forming a conducting layer 30 on the supporting layer 22 and covering the inner surface of the stack structure 20 defining the capacitor trenches and the substrate 10. The conducting layer 30 is mainly utilized as the electrode of the memory capacitor of the stack DRAM. In the embodiment, the conducting layer 30 is a titanium nitride (TiN) layer formed by means of atomic layer deposition method. Specially, the atomic layer deposition method is suitable for the growth of thin film in structures with high aspect ratio. Thereby, the conducting layer 30 has better uniformity and coverage.

Moreover, the manufacturing method further comprises the following steps to improve the electric charge stored on the capacitors.

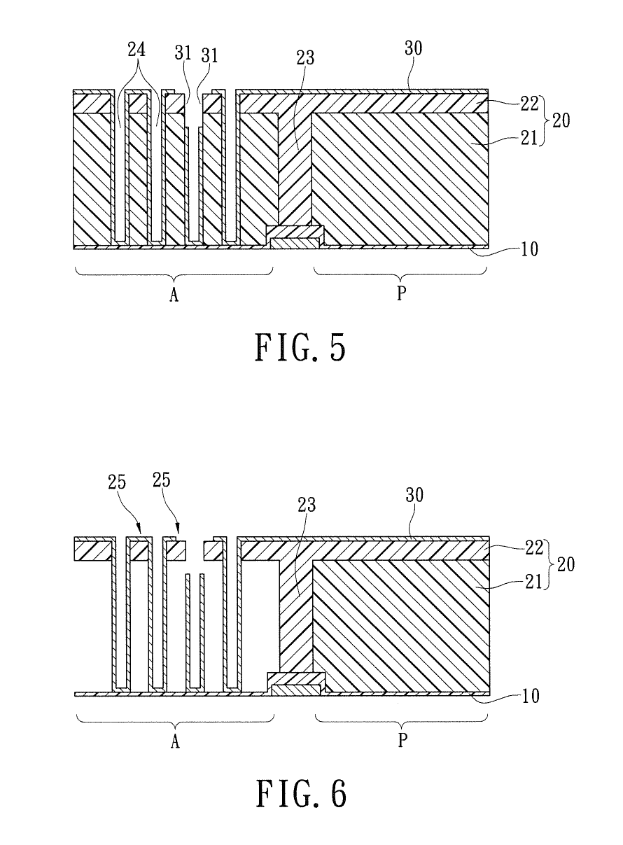

Please refer to FIGS. 5 and 6, step (f) is selectively removing the conducting layer 30 to expose the patterned sacrificial layer 21. In the embodiment, the step (f) includes the steps of forming a patterned photoresist layer to cover a selected portion the conducting layer 30 and the capacitor trenches 24 at first, then removing the uncovered conducting layer 30 by using etching solution which is used to etch titanium (Ti) or titanium nitride (TiN) to form a plurality of openings 31 for exposing the sacrificial layer 21. Step (g) is removing the exposed sacrificial layer 21 inside the annular member 23 to form a plurality of double-sided capacitors 25. Thereby, each of the double-sided capacitors has better capacitance. Specially, the conducting layer 30 is supported by the supporting layer 22 so that the double-sided capacitors 25 have improved structure strength.

Base on the above, a memory capacitor having a robust moat is further provided. The memory capacitor includes a substrate 10, a stack structure 20, a plurality row of capacitor trench 24 structures, a supporting structure, and a conducting layer 30.

In the embodiment, the substrate 10 includes a designated array area A, and the stack structure 20 formed on the substrate. The capacitor trench 24 structures are formed through the stack structure 20 in the array area A electrically connected to the substrate 10. The supporting structure includes an insulating supporting moat 21B structure arranged around the capacitor trench 24 structures through the stack structure 20 and an integrally connected supporting layer 22 over the supporting moat 21B structure. The conducting layer 30 is disposed on the supporting layer 22 in connection with the capacitor trench 24 structures.

Therefore, In comparison with prior art, the manufacturing method of the present invention has the following advantages:

1. The manufacturing method of the present invention using two etching step to form the moat and the capacitor trenches. Thus, the critical dimensions of the moat and the capacitor trenches are easily controlled by adjusting process parameters such as gaseous flow, process time, etc. Thereby, the capacitor trenches are uniform.
2. The annular member fabricated by the manufacturing method having a moat and a supporting layer filled therein. Thus, the supporting layer will be used as a mask to protect the moat form damaging by a wet etching step using stronger acid. Thereby, the manufacturing method can improve the manufacturing yield.
3. The double-sided capacitors fabricated by the manufacturing method have improved structural strength and higher charge capacity.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A manufacturing method for memory capacitor having a robust moat, comprising the steps of:
providing a substrate;
forming a patterned sacrificial layer on the substrate, the patterned sacrificial layer including a moat that surroundingly defines an array area therein and a peripheral area thereout;
forming a supporting structure by filling the moat to form an annular member and disposing a supporting layer on the sacrificial layer over the annular member, the supporting layer and the sacrificial layer forming a stack structure;
forming a plurality row of capacitor trenches in the array area through the supporting layer and the sacrificial layer of the stack structure; and
forming a conducting layer on the supporting layer and the inner surface of the capacitor trench.

2. The manufacturing method according to claim 1, further comprising the steps of:
selectively removing the conducting layer to expose the sacrificial layer; and
removing the sacrificial layer in the array area to form a plurality of double-sided capacitor structures.

3. The manufacturing method according to claim 2, wherein the step of selective removal of the conducting layer comprises the steps of:
forming a patterned photoresist layer to cover a selected portion of the conducting layer and the capacitor trenches; and
removing the uncovered conducting layer to form a plurality of openings to expose the sacrificial layer.

4. The manufacturing method according to claim 2, wherein the sacrificial layer inside the annular member is removed by a wet etching step using hydrofluoric acid.

5. The manufacturing method according to claim 1, wherein the conducting layer is a titanium nitride layer, wherein the titanium nitride layer is formed by means of atomic layer deposition method.

6. The manufacturing method according to claim 1, wherein the step of forming a patterned sacrificial layer on the substrate comprising the steps of:
forming a patterned photoresist layer on the sacrificial layer; and
removing the exposed sacrificial layer to form the annular moat.

7. The manufacturing method according to claim 1, wherein the step of forming a plurality row of capacitor trenches on the substrate comprising the steps of:
forming a patterned photoresist layer on the supporting layer; and
removing the exposed supporting layer to form the capacitor trenches, wherein each of the capacitor trench is substantially cylindrical in shape.

8. A memory capacitor having a robust moat, comprising:
a substrate having a designated array area;
a stack structure formed on the substrate;
a plurality row of capacitor trench structures formed through the stack structure in the array area electrically connected to the substrate;
a supporting structure including an insulating supporting moat structure arranged around the capacitor trench structures through the stack structure and an integrally connected supporting layer over the supporting moat structure; and
a conducting layer disposed on the supporting layer in connection with the capacitor trench structures.

9. The memory capacitor according the claim 8, wherein the stack structure includes a sacrificial layer and a supporting layer formed thereon.

10. The memory capacitor according the claim 8, wherein the moat is annular-shaped, and the capacitor trench structures are cylindrical in shape.
